(19) United States
(12) Patent Application Publication
(10) Pub. No.: US 2012/0271586 A1
(43) Pub. Date: Oct. 25, 2012

(54) TESTING MODULE FOR GENERATING ANALOG TESTING SIGNAL TO EXTERNAL DEVICE UNDER TEST, AND RELATED TESTING METHOD AND TESTING SYSTEM THEREOF

(76) Inventors: Ching-Cheng Wang, Hsinchu County (TW); Chun-Chieh Shih, Hsin-Chu Hsien (TW)

(21) Appl. No.: 13/090,247

(22) Filed: Apr. 19, 2011

(51) Int. Cl. G06F 19/00; G01R 31/00

(52) U.S. Cl. 702/119

(57) ABSTRACT

A testing module for generating an analog testing signal for a device under test includes a control circuit, a core circuit, and a connector. The core circuit is coupled to the control circuit, and arranged to generate the analog testing signal under control of the control circuit. The connector is coupled to the core circuit, and arranged to receive the analog testing signal generated from the core circuit and output the received analog testing signal. In addition, a testing method for generating an analog testing signal for a device under test includes: generating the analog testing signal by utilizing a testing module with a connector; and outputting the analog testing signal through the connector.

### BACKGROUND

The disclosed embodiments of the present invention relate to testing a specific function of a device, and more particularly, to a testing module for generating an analog testing signal to an external device under test, and related testing method and testing system thereof.

As to the functionality testing of a chip having an analog-to-digital converter (ADC) included therein, an analog testing signal is required to be fed into an analog input pin of the chip. In general, a sine-wave testing signal is commonly used as the analog testing signal to verify whether the chip is capable of satisfying the intended specifications and functional requirements of an actual application. When the frequency of the sine-wave testing signal becomes higher, the signal quality requirement of the sine-wave testing signal would become stricter. Besides, the frequency and/or voltage swing of the sine-wave testing signal may require adjustment during the functionality testing process.

In general, the conventional testing method for testing functionality of a chip uses a circuit board (e.g., a load board) to carry the chip to be tested and additional testing-related circuit component(s) used for ensuring that the desired testing performance is achieved. However, such a design has some drawbacks/disadvantages. For example, there is a tradeoff between the performance of testing the chip disposed on the circuit board and the circuit board's available circuit area needed for placing other circuit component(s). Thus, the conventional testing method still has room for improvement.

### SUMMARY

In accordance with exemplary embodiments of the present invention, a testing module for generating an analog testing signal to an external device under test and related testing method and testing system thereof are proposed to solve the above-mentioned problem.

According to a first aspect of the present invention, an exemplary testing module for generating an analog testing signal for a device under test is disclosed. The exemplary testing module includes a control circuit, a core circuit, and a connector. The core circuit is coupled to the control circuit, and arranged to generate the analog testing signal under control of the control circuit. The connector is coupled to the core circuit, and arranged to receive the analog testing signal generated from the core circuit and output the received analog testing signal.

According to a second aspect of the present invention, an exemplary testing method for generating an analog testing signal for a device under test is disclosed. The exemplary testing method includes: generating the analog testing signal by utilizing a testing module with a connector; and outputting the generated analog testing signal through the connector.

According to a third aspect of the present invention, an exemplary testing system is disclosed. The exemplary testing system includes a device under test and a testing module. The testing module includes a control circuit, a core circuit, and a connector. The core circuit is coupled to the control circuit, and arranged to generate an analog testing signal under control of the control circuit. The connector is coupled between the core circuit and the device under test, and arranged to receive the analog testing signal generated from the core circuit and output the received analog testing signal to the device under test.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a testing module according to an exemplary embodiment of the present invention.

FIG. 2 is a diagram illustrating an exemplary testing system having a testing module operated under a first operation mode.

FIG. 3 is a flowchart illustrating an exemplary testing method performed under the first operation mode.

FIG. 4 is a diagram illustrating an exemplary testing system having a testing module operated under a second operation mode.

FIG. 5 is a flowchart illustrating an exemplary testing method performed under the second operation mode.

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is electrically connected to another device, that connection may be through a direct electrical connection, or through an indirect electrical connection via other devices and connections.

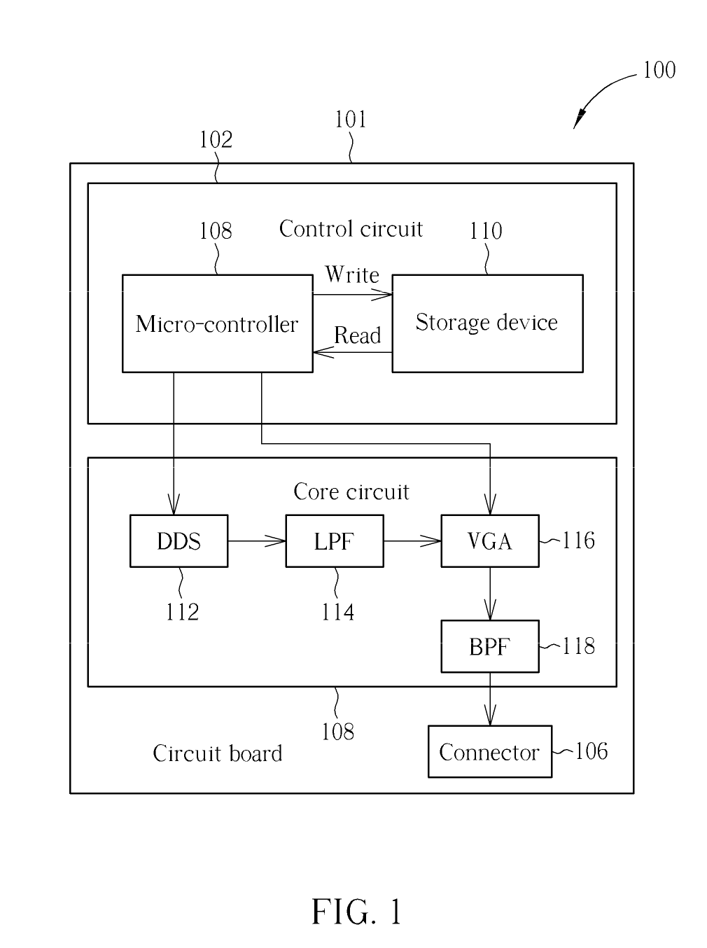

Please refer to FIG. 1, which is a diagram illustrating a testing module according to an exemplary embodiment of the present invention. The exemplary testing module 100 includes, but is not limited to, a control circuit 102, a core circuit 104 coupled to the control circuit 102, and a connector 106 coupled to the core circuit 104, wherein the control circuit 102, the core circuit 104, and the connector 106 are all disposed on the same circuit board 101. The control circuit 102 is used to control the operation of the core circuit 104, and includes, but is not limited to, a micro-controller 108 and a storage device 110. The storage device 110 may be a non-volatile memory, such as an electrically-erasable programmable read-only memory (EEPROM). The micro-controller 108 accesses (reads/writes) the storage device 110 for storing data into and retrieve data from the storage device 110. The core circuit 104 is used to generate an analog testing signal for a device under test (DUT), and includes, but is not limited, a direct digital synthesizer (DDS) 112, a low-pass filter (LPF) 114, a variable gain amplifier (VGA) 116, and a band-pass filter (BPF) 118. The connector 106 may be a high-speed connector, and is used for receiving the analog testing signal generated from the core circuit 104 and outputting the received analog testing signal. In other words, the connector 106 acts as an output interface of the testing module 100. In this exemplary embodiment, the testing module 100 may be operated under two operation modes, such as a debugging mode and a testing mode. Further details are described as follows.

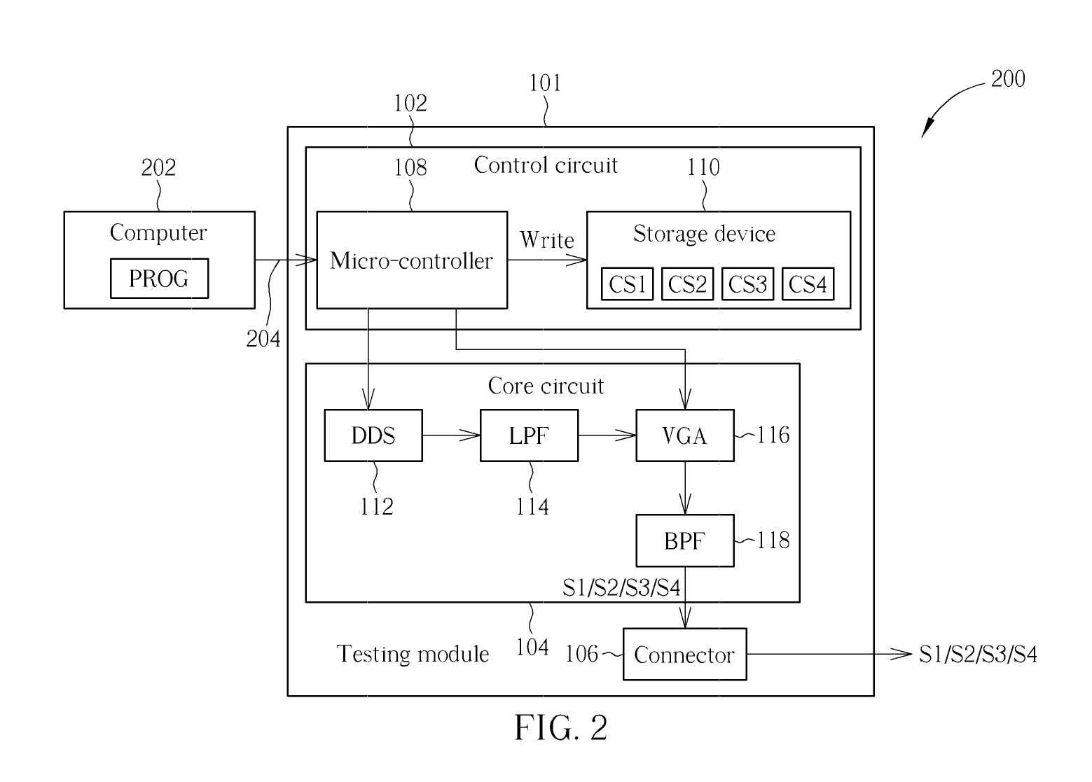

Please refer to FIG. 2, which is a diagram illustrating an exemplary testing system having a testing module operated under a first operation mode. When the testing module 100 shown in FIG. 1 is operated under the first operation mode (e.g., the debugging mode), an external computer (e.g., a laptop) 202 is coupled to the testing module 100 via a connection interface 204. For example, the connection interface 204 may be an RS232 (Recommended Standard 232) connection or a UART (Universal Asynchronous Receiver/Transmitter) connection. However, this is for illustrative purposes only, and is not meant to be a limitation of the present invention. That is, any means callable of allowing the computer 202 to communicate with the micro-controller 108 may be employed by the exemplary testing system 200 of the present invention. With the help of the connection interface 204 supported by both of the computer 202 and the micro-controller 108, the external computer 202 is allowed to control the micro-controller 108 of the testing module 100 by running a customized software program PROG. That is, regarding the exemplary testing system 200 shown in FIG. 2, the testing module 100 shown in FIG. 1 operates in response to software control of the external computer 202.

In the debugging mode, the computer 202 generates a plurality of software-based control settings (e.g., CS1, CS2, CS3, and CS4) of the analog testing signal to the micro-controller 108. Next, the micro-controller 108 stores the received software-based control settings CS1, CS2, CS3, and CS4 into the storage device 110, and controls the core circuit 104 according to the received software-based control settings CS1, CS2, CS3, and CS4. Please note that the number of software-based control settings is for illustrative purposes only, and is not meant to be a limitation of the present invention. By way of example, but not limitation, each of the software-based control settings CS1, CS2, CS3, and CS4 includes a frequency control parameter and a voltage swing control parameter. Therefore, based on the software-based control setting CS1, the micro-controller 108 controls the DDS 112 to generate a sine-wave signal with a frequency designated by the frequency control parameter of the software-based control setting CS1, and controls the VGA (e.g., an ultralow distortion intermediate-frequency VGA) 116 to make the sine-wave signal have a voltage swing designated by the voltage swing control parameter of the software-based control setting CS1.

To put it another way, the DDS 112 generates a sine-wave signal with a designated frequency and the VGA 116 makes the generated sine-wave signal have a designated voltage swing. The LPF 114 and the BPF 118 are properly designed to improve the signal quality of the sine-wave signal which acts as an analog testing signal S1 generated from the core circuit 104 under the control of the micro-controller 108. The analog testing signal S1 generated in the debugging mode is outputted from the connector 106 to an external monitoring/measuring instrument (not shown), such as a scope and an analyzer. The frequency and voltage swing of the analog testing signal S1 are verified to see if the analog testing signal S1 satisfies the desired specification. For example, if the frequency and/or the voltage swing of the analog testing signal S1 are deviated from the desired values, the computer 202 running the customized software program PROG would update the software-based control setting CS1 and transmit the updated software-based control setting CS1 to the micro-controller 108. Upon receiving the updated software-based control setting CS1 including updated frequency control parameter and/or updated voltage swing control parameter, the micro-controller 108 updates the software-based control setting CS1 stored in the storage device 110, and controls the core circuit 104 to generate the analog testing signal S1 having an updated frequency and/or an updated voltage swing. The testing module 100 does not stop calibrating the analog testing signal S1 until the analog testing signal S1 meets the desired specification.

Similarly, based on the software-based control settings CS2-CS4 generated and/or updated by the computer 202 running the customized software program PROG, the micro-controller 108 controls the core circuit 104 to generate respective sine-wave signals acting as analog testing signals S2-S4 that meet the desired specifications.

After the analog testing signals S1-S4 are successfully calibrated to thereby have designated frequencies and voltage swings, desired software-based control settings CS1-CS4 properly configured by the external computer 202 are now stored in the storage device 110.

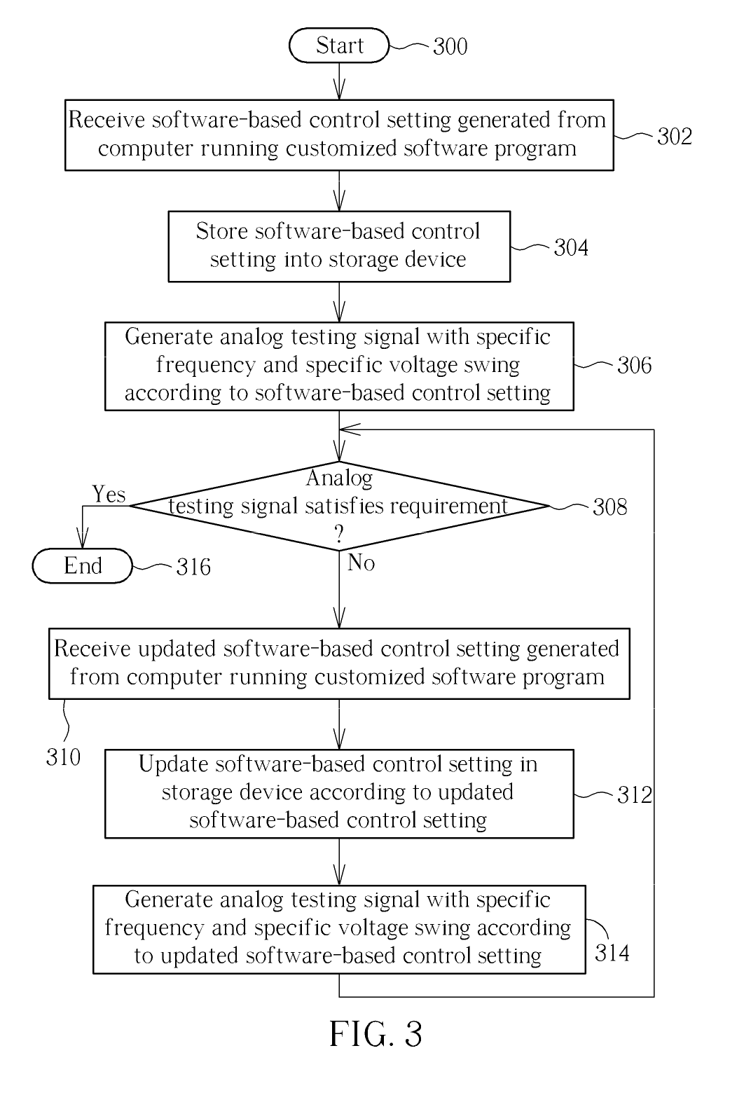

Please refer to FIG. 3, which is a flowchart illustrating an exemplary testing method performed under the first operation mode. If the result is substantially the same, the steps are not required to be executed in the exact order shown in FIG. 3. The testing method may be employed by the testing module 100 operated under the first operation mode (e.g., the debugging mode), and may be briefly summarized as follows.

Step 300: Start.

Step 302: Receive a software-based control setting generated from a computer running a customized software program.

Step 304: Store the software-based control setting into a storage device.

Step 306: Generate an analog testing signal with a specific frequency and a specific voltage swing according to the software-based control setting.

Step 308: Check if the analog testing signal satisfies the requirement. If yes, go to step 316; otherwise, go to step 310.

Step 310: Receive an updated software-based control setting generated from the computer running the customized software program.

Step 312: Update the software-based control setting in the storage device according to the updated software-based control setting.

Step 314: Generate an analog testing signal with a specific frequency and a specific voltage swing according to the updated software-based control setting. Go to step 308.

Step 316: End.

As a person skilled in the art can readily understand the operation of each step shown in FIG. 3 after reading above paragraphs directed to the testing system 200 shown in FIG. 2, further description is omitted here for brevity.

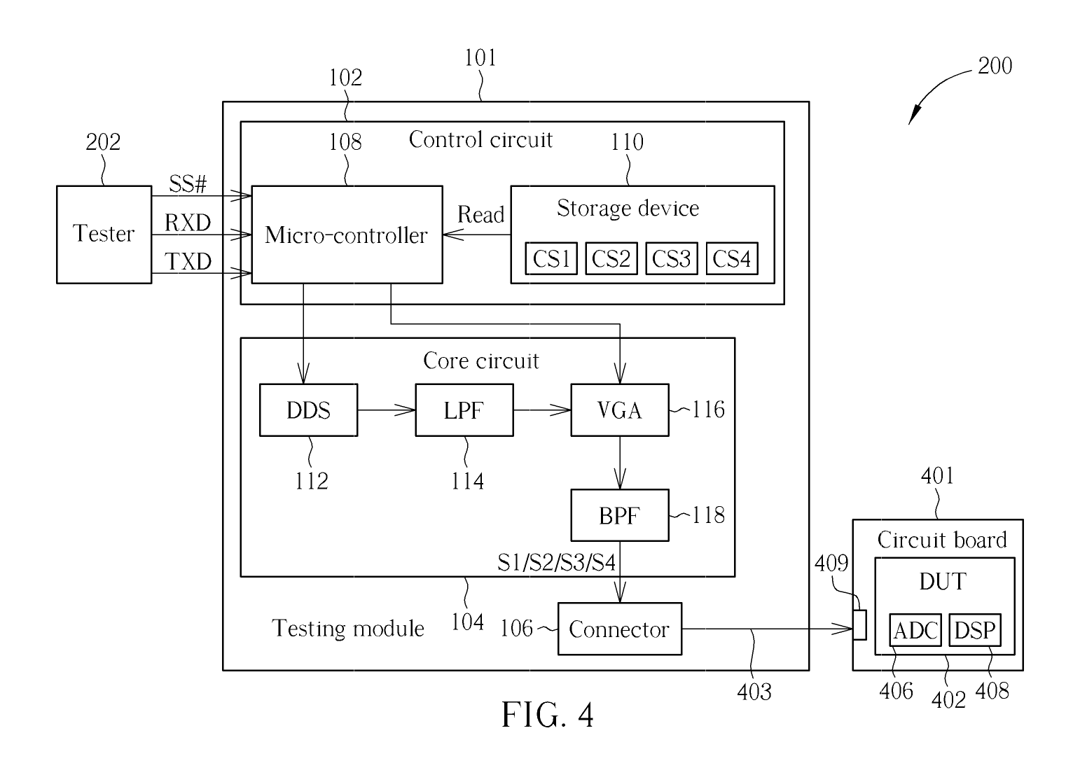

Please refer to FIG. 4, which is a diagram illustrating an exemplary testing system having a testing module operated under a second operation mode. When the testing module 100 shown in FIG. 1 is operated under the second operation mode (e.g., the testing mode), a DUT 402 having an analog-to-digital converter (ADC) 406 and a digital signal processor (DSP) 408 included therein is coupled to the connector 106 through a connector 409. For example, the DUT 402 may be a chip including an intermediate-frequency demodulator ADC. In this exemplary embodiment, the DUT 402 is disposed on a circuit board (e.g., a load board) 401 different from the circuit board 101 on which the testing module 100 is disposed. In one exemplary design, the DUT 402 is coupled to the core circuit 104 through connectors 106, 409 and a cable 403. In an alternative design, the connector 106 on the circuit board 101 may be directly connected to the connector 409 on the circuit board 401. That is, one of the connectors 106 and 409 is a male connector, and the other of the connectors 106 and 409 is a female connector. Therefore, the circuit board 101 may be removably attached to the circuit board 404 through the connectors 106 and 409. Moreover, the testing system 200 also includes a tester 404 of the DUT 401, and the micro-controller 108 is coupled to a tester channel through pins SS#, RXD, and TXD. By way of example, but not limitation, the tester 404 may be a low-end tester without the analog instrument option. In other words, the analog testing signal required by the DUT 402 is generated by the testing module 100 instead of the tester 404.

When the testing module 100 is operated under the second operation mode (e.g., the testing mode), the micro-controller 108 is further arranged to receive a hardware-based control setting generated from the tester 404. That is, regarding the exemplary testing system 200 shown in FIG. 4, the testing module 100 shown in FIG. 1 operates in response to hardware control of the external tester 404. For example, the pin SS# receives two bits of the hardware-based control setting for selecting one of the four software-based control settings CS1-CS4 stored in the storage device 110. Therefore, the frequency and/or the voltage swing of the analog testing signal (e.g., a sine-wave signal) can be changed on-the-fly by switching between the stored software-based control settings.

Upon receiving the hardware-based control setting, the micro-controller 108 reads a stored software-based control setting from the storage device 110 according to the hardware-based control setting, and controls the core circuit 104 according to the stored software-based control setting. For example, when the tester 404 requires the analog testing signal S1 that is a sine-wave signal with the desired frequency and voltage swing for testing the functionality of the DUT 402 with the ADC included therein, two bits received by the pin SS# would indicate that the software-based control setting CS1 in the storage device 110 should be used. The micro-controller 108 therefore reads the software-based control setting CS1 from the storage device 110, and controls the DDS 112 and the VGA 116 in the core circuit 104 according to the software-based control setting CS1. Thus, the DDS 112 generates a sine-wave signal with the desired frequency, and the VGA 116 makes the generated sine-wave signal have the desired voltage swing. In other words, the analog testing signal S1 with the desired frequency and voltage swing is generated from the core circuit 104, and then outputted to the DUT 402 through the connector 106. Next, the DSP 408 of the DUT 402 may perform ABIST to verify whether the DUT 401 passes the functionality test.

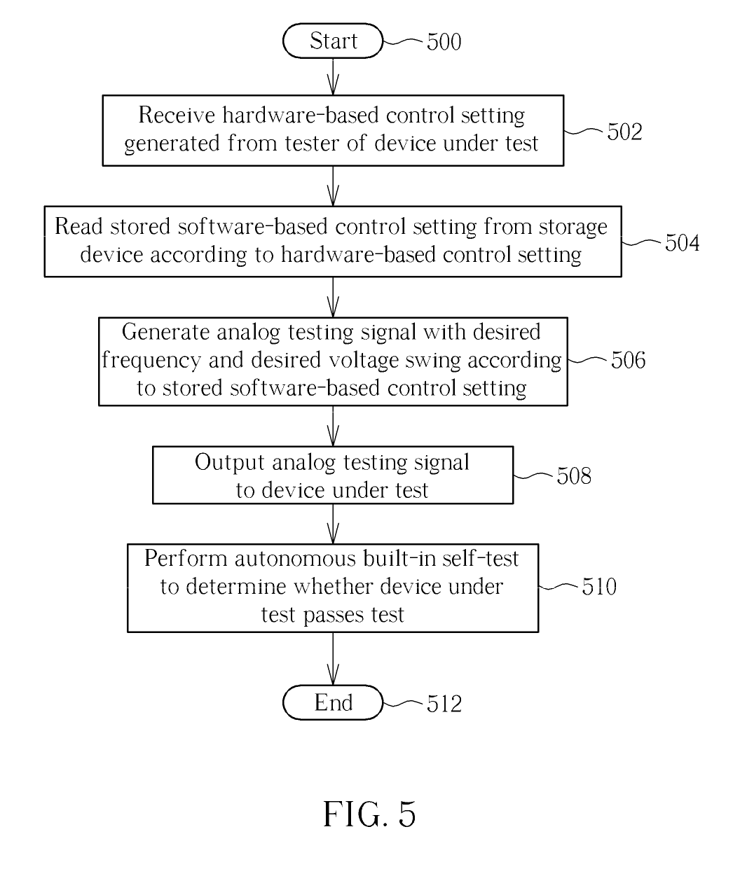

Please refer to FIG. 5, which is a flowchart illustrating an exemplary testing method performed under the second operation mode. If the result is substantially the same, the steps are not required to be executed in the exact order shown in FIG. 5. The testing method may be employed by the testing module 100 operated under the second operation mode (e.g., the testing mode), and may be briefly summarized as follows.

Step 500: Start.

Step 502: Receive a hardware-based control setting generated from a tester of a device under test.

Step 504: Read a stored software-based control setting from a storage device according to the hardware-based control setting.

Step 506: Generate an analog testing signal with a desired frequency and a desired voltage swing according to the stored software-based control setting.

Step 508: Output the analog testing signal to the device under test.

Step 510: Perform an autonomous built-in self-test (ABIST) to determine whether the device under test passes the test.

Step 512: End.

As a person skilled in the art can readily understand the operation of each step shown in FIG. 5 after reading above paragraphs directed to the testing system 200 shown in FIG. 4, further description is omitted here for brevity.

The use of the exemplary testing module (e.g., an ASIC module) which is capable of providing a needed analog testing signal to a device under test has certain advantages/benefits over other designs. For example, one testing method for testing functionality of a chip is to use automatic test equipment (ATE) with an analog source and capture instrument option. For example, a tester (e.g., the ATE) is coupled to a load board on which a device under test (e.g., the chip having the ADC included therein) through probes for feeding an analog testing signal (e.g., a sine-wave testing signal) into the device under test (DUT) and reading a testing result generated from the DUT. The testing result is analyzed by the tester to determine whether the DUT passes the functionality test.

However, using such a testing method would increase the cost of functionality testing. Besides, as a longer signal trace routed on the load board is required, the analog test signal is subject to signal attenuation and/or noise interference. Thus, the signal trace used for transmitting the analog testing signal may require shielding and have higher priority, which affects placement of other circuit components on the same load board and/or increases the number of load board layers. Moreover, to meet the signal quality requirement of the analog testing signal, the load board may require complicated filters disposed thereon to filter out undesired noise, which inevitably occupies part of the circuit area available on the load board and affects the placement of other circuit components on the same load board. Therefore, the testing method generally increases the circuit area available for circuit component placement on the load board at the expense of functionality testing performance. For example, an analog testing signal with a lower frequency is fed into the DUT disposed on the load board. As the signal quality requirement can be met by such a low-frequency analog testing signal under a condition where the complicated filters are omitted from the load board, the circuit area originally occupied by the complicated filters is now available for placing other circuit component(s).

Besides, another testing method for testing a chip having an ADC included therein is to use an on-board application-specific integrated circuit (ASIC) solution. An ASIC and the DUT (e.g., the chip having the ADC included therein) are both disposed on the same load board, where the ASIC is used for generating an analog testing signal (e.g., a sine-wave testing signal) to the DUT. Regarding the DUT, it may have a digital signal processor (DSP) implemented for performing an analog built-in self-test (ABIST) to verify whether the DUT passes the functionality test. However, using such a testing method requires an ASIC placed on the same load board on which the DUT is disposed, which inevitably occupies a large circuit area on the load board and affects the placement of other circuit components on the same load board. In addition, the DUT should be particularly designed to have the capability of controlling the on-board ASIC for the frequency and/or voltage swing of the sine-wave testing signal dynamically.

Compared to the aforementioned testing method which uses an ATE with an analog source and capture instrument option, the exemplary testing method of the present invention has lower cost of functionality testing, higher signal quality of the analog testing signal, smaller occupied circuit area, and higher convenience/flexibility.

Moreover, compared to the aforementioned testing method which uses an on-board ASIC solution, the exemplary testing method of the present invention has smaller occupied circuit area and higher convenience/flexibility. More specifically, as the functionality of each circuit component of the testing module 100 has been verified in advance, the performance of the testing module 100 is guaranteed without any compromise. The testing module 100 is disposed on a circuit board 101 external to the circuit board 401 on which the DUT 402 is disposed. Thus, the size of circuit area occupied by load board can be minimized as the load board only has a small portion of the circuit area that is occupied by one additional component (i.e., the connector 409). As there is no need to use the device under test to control the on-board ASIC, the relay switching between a tester channel and a control channel may be omitted, thus further reducing the occupied circuit area and avoiding the uncertainty of the ABIST control firmware. The debugging ability is greatly improved by using the customized software program PROG to control the DDS 112 and PGA 116 of the core circuit 104 for frequency and voltage swing calibration. The signal quality of the analog testing signal generated from the testing module 100 may be carefully verified in advance by using the external scope and analyzer, thereby reducing the uncertainty of the analog testing signal generation. Moreover, the testing module 100 is a removable hardware module, and can be used in different products. Moreover, when the circuit design of the testing module 100 needs some modifications, the lead time of the testing module 100 is shorter than that of the on-board ASIC solution, the cost of the testing module 100 is lower than that of the on-board ASIC solution, and the convenience/flexibility of the testing module 100 is higher than that of the on-board ASIC solution.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A testing module for generating an analog testing signal for a device under test, the testing module comprising:
a control circuit;
a core circuit, coupled to the control circuit, the core circuit arranged to generate the analog testing signal under control of the control circuit; and
a connector, coupled to the core circuit, the connector arranged to receive the analog testing signal generated from the core circuit, and output the received analog testing signal.

2. The testing module of claim 1, wherein the control circuit comprises:
a micro-controller, arranged to receive a software-based control setting of the analog testing signal and control the core circuit according to the software-based control setting when the testing module is operated under a first operation mode.

3. The testing module of claim 2, wherein the software-based control setting is received from a computer running a software program when the testing module is operated under the first operation mode.

4. The testing module of claim 2, wherein the control circuit further comprises:
a storage device, arranged to store the software-based control setting;
wherein when the testing module is operated under a second operation mode, the micro-controller is further arranged to receive a hardware-based control setting, read the stored software-based control setting from the storage device according to the hardware-based control setting, and control the core circuit according to the stored software-based control setting.

5. The testing module of claim 4, wherein the software-based control setting is received from a computer running a software program when the testing module is operated under the first operation mode, and the hardware-based control setting is received from a tester of the device under test when the testing module is operated under the second operation mode.

6. The testing module of claim 1, wherein the control circuit comprises:
a storage device, arranged to store a control setting of the analog testing signal; and
a micro-controller, coupled to the storage device, the micro-controller arranged to receive a hardware-based control setting, read the stored control setting from the storage device according to the hardware-based control setting, and control the core circuit according to the stored control setting.

7. The testing module of claim 6, wherein the hardware-based control setting is received from a tester of the device under test.

8. The testing module of claim 1, wherein the control circuit, the core circuit, and the connector are all disposed in a same circuit board.

9. A testing method for generating an analog testing signal for a device under test, comprising:
generating the analog testing signal by utilizing a testing module with a connector; and
outputting the analog testing signal through the connector.

10. The testing method of claim 9, wherein the step of generating the analog testing signal comprises:
receiving a software-based control setting of the analog testing signal in a first operation mode; and
generating the analog testing signal according to the software-based control setting.

11. The testing method of claim 10, wherein the step of receiving the software-based control setting comprises:
receiving the software-based control setting from a computer running a software program.

12. The testing method of claim 10, wherein the step of generating the analog testing signal further comprises:
storing the software-based control setting in a storage device; and
the testing method further comprises:
receiving a hardware-based control setting in a second operation mode;
reading the stored software-based control setting from the storage device according to the hardware-based control setting; and
generating the analog testing signal according to the stored software-based control setting.

13. The testing method of claim 12, wherein the step of receiving the software-based control setting comprises: receiving the software-based control setting from a computer running a software program, and the step of receiving the hardware-based control setting comprises: receiving the hardware-based control setting from a tester of the device under test.

14. The testing method of claim 9, wherein the step of generating the analog testing signal comprises:
storing a control setting of the analog testing signal in a storage device; and
receiving a hardware-based control setting, reading the stored control setting from the storage device according to the hardware-based control setting, and generating the analog testing signal according to the stored control setting.

15. The testing method of claim 14, wherein the step of receiving the hardware-based control setting comprises:
receiving the hardware-based control setting from a tester of the device under test.

16. A testing system, comprising:
a device under test; and
a testing module, comprising:
a control circuit;
a core circuit, coupled to the control circuit, the core circuit arranged to generate an analog testing signal under control of the control circuit; and
a connector, coupled between the core circuit and the device under test, the connector arranged to receive the analog testing signal generated from the core circuit, and output the received analog testing signal to the device under test.

17. The testing system of claim 16, wherein the control circuit comprises:
a storage device, arranged to store a control setting of the analog testing signal; and
a micro-controller, coupled to the storage device, the micro-controller arranged to receive a hardware-based control setting, read the stored control setting from the storage device according to the hardware-based control setting, and control the core circuit according to the stored control setting.

18. The testing system of claim 17, further comprising:
a tester of the device under test, arranged to generate the hardware-based control setting to the micro-controller.

19. The testing system of claim 16, wherein the device under test is disposed in a first circuit board, and the control circuit, the core circuit, and the connector are all disposed in a same second circuit board.
